(19) United States
(12) Patent Application Publication
(10) Pub. No.: US 2026/0277472 A1
(43) Pub. Date: Sep. 17, 2026

(54) MEMORY DEVICE AND COMPUTING DEVICE

(71) Applicant: SK hynix Inc., Icheon-si Gyeonggi-do (KR)

(72) Inventor: Beom Ju SHIN, Icheon-si Gyeonggi-do (KR)

(73) Assignee: SK hynix Inc., Icheon-si Gyeonggi-do (KR)

(21) Appl. No.: 19/550,865

(22) Filed: Feb. 26, 2026

Related U.S. Application Data
(60) Provisional application No. 63/770,144, filed on Mar. 11, 2025.

(30) Foreign Application Priority Data
Nov. 17, 2025 (KR) 10-2025-0173751

(51) Int. Cl. G06F 3/06; G06F 7/50; G06F 7/523; G11C 11/54; G11C 16/04; G11C 16/24; G11C 16/26

(52) U.S. Cl. CPC G06F 3/0656; G06F 3/0604; G06F 3/0679; G06F 7/50; G06F 7/523; G11C 11/54; G11C 16/0483; G11C 16/24; G11C 16/26

(57) ABSTRACT

A memory device includes a plurality of non-volatile memory cells connected to word lines and bit lines. The memory device includes a plurality of buffer circuits coupled to the memory cell array. The plurality of buffer circuits are configured to, in a deep neural network computing operation, store values read from selected memory cells of the memory cell array, and perform multiplication operations using the stored values and corresponding input data values.

### CROSS-REFERENCES TO RELATED APPLICATION

The present application claims benefit under 35 U.S.C. § 119(e) of U.S. Provisional application No. 63/770,144 filed on Mar. 11, 2025, and claims priority under 35 U.S.C. § 119(a) to Korean application number 10-2025-0173751 filed on Nov. 17, 2025, in the Korean Intellectual Property Office, which applications are incorporated herein by reference in their entirety.

### BACKGROUND

### 1. Technical Field

Various embodiments of the present disclosure generally relate to a computing device, and more particularly, to a computing device including a memory device.

### 2. Related Art

Recently, artificial intelligence (AI) technologies have required increasingly high-performance computing capability and large-capacity memory, and cloud-based computing systems including a graphics processing unit (GPU) and high bandwidth memory (HBM) have typically been employed for these purposes. However, in mobile terminals such as smartphones, it may be difficult to perform computationally intensive AI operations at a cloud level due to limitations in computing power, memory capacity, and battery resources. Nevertheless, on-device AI can provide basic AI services with relatively limited computing resources by adopting comparatively simple AI models. Accordingly, technologies for performing computations by utilizing Universal Flash Storage (UFS) or NOT AND (NAND) flash memory, which are non-volatile storage devices embedded in mobile terminals, have recently been actively researched.

### SUMMARY

In an embodiment, a memory device includes a memory cell array and a plurality of page buffers. The memory cell array may include memory cells connected to word lines and bit lines, and the memory cells may be NAND flash memory cells. The plurality of page buffers may be configured to, in a deep neural network computing operation, store first values read from first memory cells connected to a first word line among the word lines through the bit lines, and may be configured to respectively perform multiplication operations on inputs and the first values.

In an embodiment, a memory device includes a memory cell array, a plurality of page buffers, and a plurality of majority check circuits. The memory cell array may include memory cells connected to word lines and bit lines, and the memory cells may be NAND flash memory cells. The plurality of page buffers may be configured to, in a deep neural network computing operation, store first values read from first memory cells connected to a first word line among the word lines through the bit lines, and may be configured to respectively perform multiplication operations on inputs and the first values. The plurality of majority check circuits may be respectively connected to a plurality of page buffer groups into which the plurality of page buffers are divided. Each of the plurality of majority check circuits may be configured to, in the deep neural network computing operation, perform a majority check operation on multiplication results received from one or more corresponding page buffers included in a corresponding page buffer group and output a final multiplication result.

In an embodiment, a computing device includes a memory device and a controller. The memory device may include memory cells connected to word lines and bit lines, and the memory cells may be NAND flash memory cells and may include first memory cells connected to a first word line among the word lines, the first memory cells storing first parameters corresponding to input connections of nodes of a first hidden layer of a deep neural network. The controller may be configured to control the memory device to perform a deep neural network computing operation by transmitting external inputs to the memory device. The memory device may further comprise a plurality of page buffers configured to, in the deep neural network computing operation, respectively store the first parameters read from the first memory cells through the bit lines, respectively store the external inputs, and respectively perform multiplication operations on the external inputs and the first parameters.

In an embodiment, a memory device includes a plurality of non-volatile memory cells connected to word lines and bit lines. The memory device may include a plurality of buffer circuits coupled to the memory cell array. The plurality of buffer circuits may be configured to, in a deep neural network computing operation, store values read from selected memory cells of the memory cell array, and perform multiplication operations using the stored values and corresponding input data values.

### BRIEF DESCRIPTION OF THE DRAWINGS

FIG. 1A is a diagram illustrating a structure of a deep neural network.

FIG. 1B is a diagram illustrating an operation of each node of a deep neural network.

FIG. 2 is a block diagram illustrating a memory device capable of performing a deep neural network computing operation according to an embodiment of the present disclosure.

FIG. 3 is a circuit diagram illustrating a memory block according to an embodiment of the present disclosure.

FIG. 4 is a circuit diagram illustrating a page buffer according to an embodiment of the present disclosure.

FIG. 5A is a circuit diagram illustrating a fail bit counter and a pass/fail determination circuit according to an embodiment of the present disclosure.

FIG. 5B is a table illustrating a pass/fail result according to a reference signal according to an embodiment of the present disclosure.

FIG. 6 and FIG. 7 are diagrams illustrating a deep neural network computing operation of a memory device according to an embodiment of the present disclosure.

FIG. 8 is a diagram illustrating a deep neural network computing operation of a memory device according to an embodiment of the present disclosure.

FIG. 9 is a block diagram illustrating a memory device capable of performing a deep neural network computing operation according to an embodiment of the present disclosure.

FIG. 10 is a diagram illustrating a deep neural network computing operation of a memory device according to an embodiment of the present disclosure.

FIG. 11 is a block diagram illustrating a computing device performing a deep neural network computing operation according to an embodiment of the present disclosure.

### DETAILED DESCRIPTION

Hereinafter, embodiments of the present disclosure will be described in more detail with reference to the accompanying drawings.

When an element is described as being “connected” to another element in the present disclosure, the elements may be directly coupled to each other or may be coupled through one or more intervening elements.

The terms “first,” “second,” and the like used in the present disclosure are employed to distinguish between different components, and do not limit an order, importance, functional difference, or physical arrangement of the components. Even for the same component, different numbers may be used depending on an embodiment.

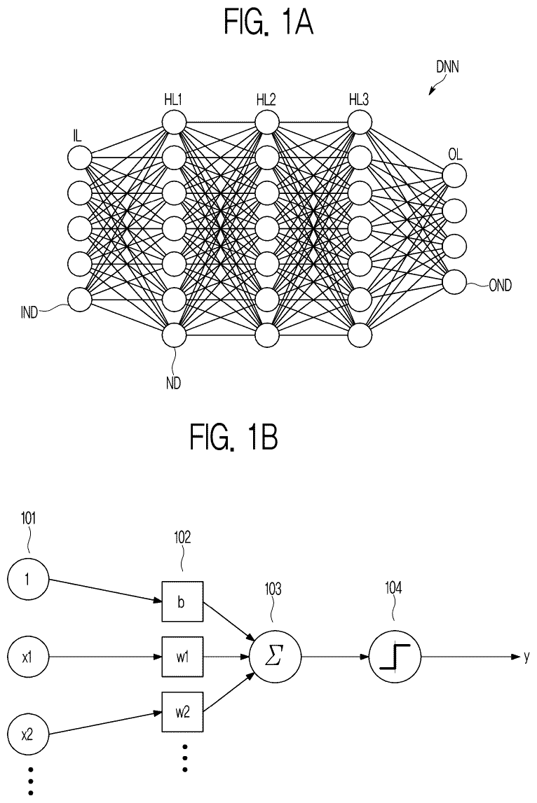

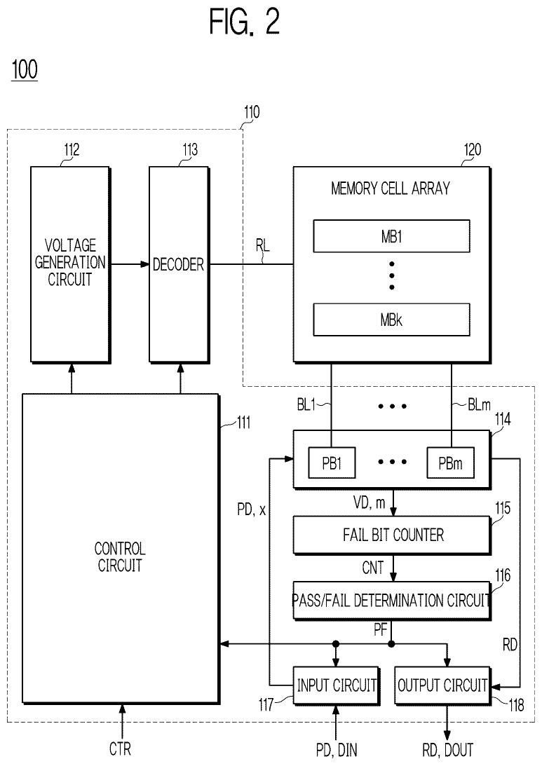

FIG. 1A is a diagram illustrating a structure of a deep neural network DNN according to an embodiment of the present disclosure.

Referring to FIG. 1A, a main structure of AI computing may include sequential matrix multiplication operations based on the deep neural network DNN. The deep neural network DNN may include an input layer IL, first to third hidden layers HL1 to HL3, and an output layer OL. The number of hidden layers included in the deep neural network DNN may be an example and may be more or less than the number shown.

The input layer IL may receive multi-dimensional input data from an external source. Each input node IND included in the input layer IL may be activated according to a corresponding dimensional component of the external input data, and the external input data may be delivered to the first hidden layer HL1 and used as initial input of the deep neural network DNN. The first to third hidden layers HL1 to HL3 may be arranged between the input layer IL and the output layer OL. Each of the first to third hidden layers HL1 to HL3 may include one or more nodes ND, receive output data from a preceding layer, and generate a new feature representation by applying weighted operations and a nonlinear activation function before delivering the generated feature representation to a subsequent layer. The output layer OL may output a result predicted or classified by an AI model. The output layer may include one or more output nodes OND depending on the intended task, and may generally apply an output-specific activation function such as a Softmax function or a Sigmoid function to generate probability-based output data for each class or result.

FIG. 1B is a diagram illustrating an operation of each node of the deep neural network DNN.

Referring to FIG. 1B, each node ND (or an artificial neuron) included in the first to third hidden layers HL1 to HL3 may serve as a calculation unit of the deep neural network DNN, may sum 103 results obtained by applying parameters 102, including a bias b and weights w1 and w2, to inputs 101, including a constant 1 and input values x1 and x2, output from a previous layer, and may generate a node computing result y to be delivered as input to a subsequent layer by applying an activation function 104 to the summation result. Through this process, the node ND may sequentially transform the inputs 101 and may contribute to allowing the deep neural network DNN to extract useful features from the external input data and to produce final output data.

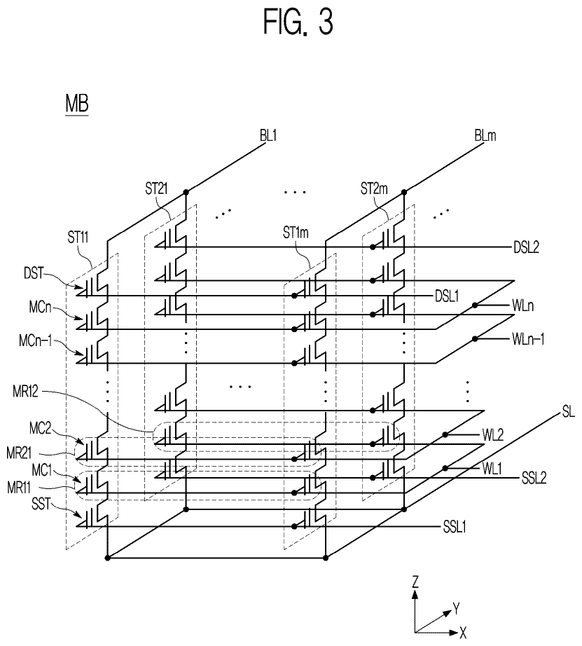

FIG. 2 is a block diagram illustrating a memory device 100 capable of performing a deep neural network computing operation according to an embodiment of the present disclosure.

In an embodiment, a deep neural network computing operation refers to an internal operation of a memory device in which dedicated hardware circuits of the memory device perform neural network inference processing on input data. During the deep neural network computing operation, input data values received from an external controller are stored in internal storage elements, such as page buffers, latches, or registers, and are propagated through a plurality of neural network layers, including at least one hidden layer, by performing weighted computation operations using parameter data stored in memory cells of the memory device. Intermediate computation results generated for one neural network layer may be stored in the page buffers and transmitted as input data values to a subsequent neural network layer under control of a control circuit. The deep neural network computing operation is distinct from program, read, and erase operations of the memory device and is executed using internal decoding, data routing, and control circuitry of the memory device. By performing the deep neural network computing operation using circuits integrated within the memory device, data movement between an external processor and the memory device is reduced, thereby decreasing memory access latency and power consumption and improving overall computational efficiency. Referring to FIG. 2, the memory device 100 may operate under control of an external device, for example, a controller. Specifically, the memory device 100 may store a program data PD received from the controller by performing a program operation in response to an external signal CTR transmitted from the controller. Also, the memory device 100 may output a read data RD to the controller by performing a read operation in response to the external signal CTR transmitted from the controller. Also, the memory device 100 may perform a deep neural network computing operation in response to the external signal CTR transmitted from the controller.

The memory device 100 may include a peripheral circuit 110 and a memory cell array 120.

The peripheral circuit 110 may perform a program operation and a read operation on the memory cell array 120.

Also, the peripheral circuit 110 may perform a deep neural network computing operation based on an external input data DIN input from the controller and parameters read from the memory cell array 120. The parameters may be stored in the memory cell array 120 through a program operation before the deep neural network computing operation is performed.

The peripheral circuit 110 may include a control circuit 111, a voltage generation circuit 112, a decoder 113, a plurality of page buffers 114, a fail bit counter 115, a pass/fail determination circuit 116, an input circuit 117, and an output circuit 118.

The control circuit 111 may control overall operations of internal circuits of the memory device 100 to perform internal operations, for example, a program operation, a read operation, an erase operation, and a deep neural network computing operation, in response to the external signal CTR. The control circuit 111 may selectively re-perform an internal operation in response to a pass/fail result PF received from the pass/fail determination circuit 116 during a predetermined internal operation, for example, the program operation, the read operation, or the erase operation.

In an embodiment, the control circuit 111 may include hardware control logic implemented using one or more finite state machines, command decoding circuitry, control registers, and timing and sequencing logic. The command decoding circuitry may be configured to decode the external control signal CTR and generate internal control signals corresponding to program, read, erase, and deep neural network computing operations. The finite state machines and timing logic may be configured to sequence and coordinate execution of the internal operations among internal circuits of the memory device 100 in accordance with predetermined operation flows. In an embodiment, the control circuit 111 may further include status evaluation logic and retry control logic configured to receive a pass/fail result PF from the pass/fail determination circuit 116 and to selectively re-perform an internal operation based on the received result. The control registers may store operation parameters, mode information, and retry-related state information used during execution of the internal operations. In some embodiments, the control circuit 111 may include or may be implemented using an embedded controller or microcontroller executing firmware stored in a non-volatile memory, in combination with the hardware control logic described above.

The voltage generation circuit 112 may generate various internal voltages and may output the internal voltages to internal circuits of the memory device 100. For example, the voltage generation circuit 112 may output a read voltage used in a read operation to the decoder 113.

In an embodiment, the voltage generation circuit 112 may include one or more voltage generation and regulation circuits configured to generate internal voltages required for operations of the memory device 100. The voltage generation circuit 112 may include, for example, charge pump circuits, voltage regulators, reference voltage generators, and voltage level shifters. The charge pump circuits may be configured to generate boosted voltages higher than an external supply voltage, and the voltage regulators may be configured to regulate the generated voltages to predetermined voltage levels. In an embodiment, the voltage generation circuit 112 may further include voltage selection and distribution circuitry configured to selectively output one or more generated internal voltages to internal circuits of the memory device 100 based on control signals received from the control circuit 111. For example, the voltage generation circuit 112 may output a read voltage, a program voltage, or an erase voltage to the decoder 113 or other internal circuits during corresponding operations. In some embodiments, the voltage generation circuit 112 may include digital to analog converters, resistor ladders, or trimming circuits configured to adjust voltage levels in accordance with operation modes or device characteristics.

The decoder 113 may be coupled to the memory cell array 120 through row lines RL. The decoder 113 may apply the internal voltages transmitted from the voltage generation circuit 112 to the row lines RL. The row lines RL may include, as will be described later, one or more drain selection lines, a plurality of word lines, and one or more source selection lines coupled to memory blocks MB1 to MBk, respectively.

In an embodiment, the decoder 113 may include row decoding circuitry configured to select one or more row lines RL coupled to the memory cell array 120 based on address information and control signals received from the control circuit 111. The decoder 113 may include address decoders, switching transistors, word line drivers, and voltage selection circuits configured to selectively apply internal voltages received from the voltage generation circuit 112 to the row lines RL. In an embodiment, the row decoding circuitry may be configured to drive the row lines RL to predetermined voltage levels during different internal operations. For example, the decoder 113 may selectively apply a read voltage, a program voltage, or an erase voltage to one or more drain selection lines, word lines, or source selection lines included in the row lines RL. The row lines RL may be coupled to corresponding memory blocks MB1 to MBk, and the decoder 113 may be configured to independently select and drive row lines associated with each memory block.

The plurality of page buffers 114 may be coupled to the memory blocks MB1 to MBk included in the memory cell array 120 through bit lines BL1 to BLm. The plurality of page buffers 114 may include page buffers PB1 to PBm respectively coupled to the bit lines BL1 to BLm.

The plurality of page buffers 114 may receive and store the program data PD to be stored in the memory cell array 120 from the input circuit 117.

Also, the plurality of page buffers 114 may store the read data RD read from the memory cell array 120 before outputting the read data RD to the output circuit 118.

Also, the plurality of page buffers 114 may transmit, to the fail bit counter 115, verification data VD that is a result of a verification operation performed to verify completion of an internal operation performed on a target region of the memory cell array 120 after an internal operation, for example, a program operation or an erase operation.

Also, one or more page buffers among the plurality of page buffers 114 may perform multiplication operations on inputs x received from the input circuit 117 and parameters read from the memory cell array 120 in a deep neural network computing operation, and may output multiplication results m to the fail bit counter 115.

The fail bit counter 115 may output a count result CNT by performing a counting operation of counting the number of fail bits from the verification data VD transmitted from the plurality of page buffers 114. For example, the fail bit counter 115 may count the number of fail bits that are identical to a predetermined value from the verification data VD that is a result of a verification operation performed for an erase operation. As another example, the fail bit counter 115 may count the number of fail bits that are identical to a predetermined value from the verification data VD that is a result of a verification operation performed for a program operation. In an embodiment, the count result CNT may be output in a digital scheme or an analog scheme (i.e., a voltage or current signal). The word “predetermined” as used herein with respect to a parameter, such as a predetermined timing, time, or voltage level, means that a value for the parameter is determined prior to the parameter being used in a process or algorithm. For some embodiments, the value for the parameter is determined before the process or algorithm begins. In other embodiments, the value for the parameter is determined during the process or algorithm but before the parameter is used in the process or algorithm.

Also, the fail bit counter 115 may receive the multiplication results m from one or more page buffers among the plurality of page buffers 114 in a deep neural network computing operation, may count the number of multiplication results that are identical to a predetermined value, and may output the count result CNT. The fail bit counter 115 may count the number of multiplication results that are identical to a predetermined value among the multiplication results input to the same node ND of the deep neural network DNN. Accordingly, in a deep neural network computing operation, the count result CNT may correspond to a result of performing a summation operation on the multiplication results input to one corresponding node ND.

The pass/fail determination circuit 116 may receive the count result CNT from the fail bit counter 115, compare the count result CNT with a predetermined reference value, and output the pass/fail result PF to the control circuit 111 by determining whether a pass or a fail occurs. For example, in an erase operation, the pass/fail determination circuit 116 may output the pass/fail result PF having a first value (for example, “1”) indicating that the erase operation is a pass when the count result CNT is equal to or less than the reference value. On the other hand, the pass/fail determination circuit 116 may output the pass/fail result PF having a second value (for example, “0”) indicating that the erase operation is a fail when the count result CNT exceeds the reference value. When the control circuit receives the pass/fail result PF indicating that the erase operation is a fail from the pass/fail determination circuit 116, the control circuit may re-perform the erase operation. The predetermined reference value may be set under control of the control circuit.

Also, the pass/fail determination circuit 116 may receive the count result CNT from the fail bit counter 115 in a deep neural network computing operation, compare the count result CNT with a predetermined reference value, and output the pass/fail result PF to the input circuit 117. Accordingly, in the deep neural network computing operation, the pass/fail result PF may correspond to a result obtained by performing an activation operation (i.e., applying an activation function) on a summation operation result in one corresponding node ND, that is, the node computing result y of the corresponding node ND.

In an embodiment, the memory device 100 may further include fail bit counters corresponding to the number of nodes included in each hidden layer and pass/fail determination circuits corresponding to the number.

The input circuit 117 may receive the program data PD to be stored in the memory cell array 120 from the controller in a program operation and may transmit the program data PD to the plurality of page buffers 114.

Also, the input circuit 117 may operate as the input layer IL of the deep neural network DNN. Specifically, in a deep neural network computing operation, the input circuit 117 may receive the external input data DIN from the controller and may transmit the external input data DIN, as inputs x transmitted from the input layer IL to the first hidden layer HL1, to one or more page buffers among the plurality of page buffers 114. The one or more page buffers to which the inputs x are transmitted may be determined according to an input connection structure between nodes of the input layer IL and the first hidden layer HL1 of the deep neural network DNN.

Also, in the deep neural network computing operation, the input circuit 117 may transmit the pass/fail result PF received from the pass/fail determination circuit 116, as inputs x transmitted from a previous hidden layer to a subsequent hidden layer, to one or more page buffers among the plurality of page buffers 114.

In an embodiment, the input circuit 117 may include input interface circuitry, data routing logic, and buffer control circuitry configured to receive input data from an external controller and selectively transmit the received data to the plurality of page buffers 114. The input interface circuitry may include input latches, serializers or deserializers, and data registers configured to capture program data PD during a program operation and external input data DIN during a deep neural network computing operation. In an embodiment, the data routing logic may be configured to distribute the received input data to selected page buffers among the plurality of page buffers 114 based on control signals received from the control circuit 111. In a program operation, the input circuit 117 may route program data PD to page buffers corresponding to target memory cells in the memory cell array 120. In a deep neural network computing operation, the input circuit 117 may route the external input data DIN as input values x corresponding to nodes of the input layer IL of the deep neural network DNN to page buffers associated with nodes of the first hidden layer HL1. In an embodiment, the input circuit 117 may further include selection and mapping circuitry configured to determine one or more page buffers to which the input values x are transmitted in accordance with an input connection structure between nodes of the input layer IL and nodes of the first hidden layer HL1. Additionally, during the deep neural network computing operation, the input circuit 117 may route a pass or fail result PF received from the pass or fail determination circuit 116 as input values x corresponding to outputs of a previous hidden layer to page buffers associated with a subsequent hidden layer. In some embodiments, the input circuit 117 may include multiplexers, demultiplexers, and control registers to support selective routing and reuse of the page buffers.

The output circuit 118 may receive the read data RD read from the memory cell array 120 from the plurality of page buffers 114 and may output the read data RD to the controller.

Also, in a deep neural network computing operation, the output circuit 118 may output final output data DOUT to the controller as final output data. The final output data DOUT may include the pass/fail result PF received from the pass/fail determination circuit 116. The output circuit 118 may operate as the output layer OL of the deep neural network DNN.

In an embodiment, the output circuit 118 may include output interface circuitry, data aggregation logic, and output buffer circuitry configured to receive data from the plurality of page buffers 114 and transmit output data to an external controller. The output interface circuitry may include output registers, serializers or deserializers, and output drivers configured to format and drive read data RD read from the memory cell array 120 during a read operation. In an embodiment, the data aggregation logic may be configured to collect data from selected page buffers and generate output data corresponding to a result of an internal operation. In a deep neural network computing operation, the output circuit 118 may generate final output data DOUT corresponding to outputs of the output layer OL of the deep neural network DNN. The final output data DOUT may include a pass or fail result PF received from the pass or fail determination circuit 116 or data derived therefrom. In an embodiment, the output circuit 118 may further include selection and routing circuitry configured to determine which data from the plurality of page buffers 114 are included in the output data based on control signals received from the control circuit 111. In some embodiments, the output circuit 118 may include multiplexers, output registers, and control logic to support selective output of read data and neural network output data.

The memory cell array 120 may include the plurality of memory blocks MB1 to MBk. Each of the plurality of memory blocks MB1 to MBk may include memory cells. Each of the plurality of memory blocks MB1 to MBk may be connected to the row lines RL and the bit lines BL1 to BLm. Each of the plurality of memory blocks MB1 to MBk may be selected for a program operation or a read operation through control of the row lines RL and the bit lines BL1 to BLm. Each memory block may be a unit in which an erase operation is performed.

In an embodiment, the memory device 100 may be a NAND flash memory device. The NAND flash memory device may be a non-volatile storage medium and may maintain data even when a power supply is cut off. The NAND flash memory device may store data by adjusting an amount of charge of a floating gate transistor to vary a threshold voltage state of each memory cell. The NAND flash memory device may be suitable for large-capacity data storage due to a high level of integration and a low-cost structure. Also, the NAND flash memory device may be effectively utilized for artificial intelligence processing such as a deep neural network computing operation based on parallel accessibility and non-volatile characteristics.

In an embodiment, the memory device 100 may include various types of memory, such as a NOR flash memory, a Resistive Random Access Memory (RRAM), a Phase-Change Memory (PRAM), a Magnetoresistive Random Access Memory (MRAM), a Ferroelectric Random Access Memory (FRAM), or a Spin Transfer Torque Random Access Memory (STT-RAM). In an embodiment, the memory cells may be implemented using non-volatile memory technologies including, but not limited to, NAND flash memory, NOR flash memory, resistive memory, phase change memory, magnetic memory, or ferroelectric memory.

In an embodiment, a deep neural network implemented by the memory device 100 may be a Binary Neural Network (BNN), but embodiments of the present disclosure are not limited thereto. For example, the deep neural network implemented by the memory device 100 may be implemented as an artificial neural network in which inputs or weights are expressed as multi-bit values.

According to various embodiments of the present disclosure, by implementing a deep neural network in the memory device 100, a cost for performing a deep neural network computing operation may be reduced compared with a case in which the deep neural network computing operation is performed by processors such as a CPU and a GPU. Also, according to various embodiments of the present disclosure, a processing speed may be improved compared with a case in which artificial intelligence of a mobile device performs a neural network computing operation in a server and receives a computation result from the server. Also, according to an embodiment of the present disclosure, a reduction in accuracy of a neural network computing operation due to cell current variability and sensing errors of page buffers may be prevented or mitigated. Also, according to an embodiment of the present disclosure, the number of hidden layers and the number of nodes per each hidden layer may be efficiently scaled.

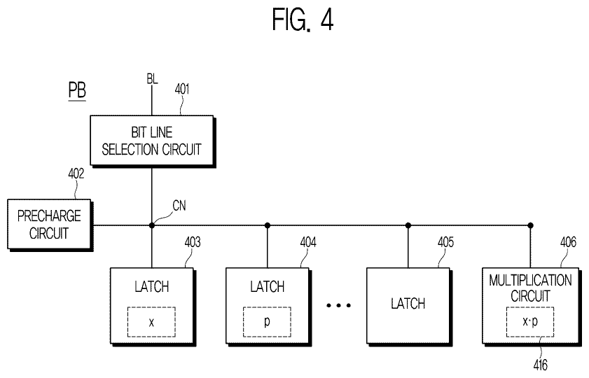

FIG. 3 is a circuit diagram illustrating a memory block MB according to an embodiment of the present disclosure. Each of the memory blocks MB1 to MBk of FIG. 2 may be configured similarly to the memory block MB of FIG. 3

Referring to FIG. 3, the memory block MB may be coupled to the peripheral circuit 110 through drain selection lines DSL1 and DSL2, source selection lines SSL1 and SSL2, word lines WL1 to WLn, bit lines BL1 to BLm, and a source line SL.

The memory block MB may include strings ST11 to ST1m, ST21 to ST2m. Each of the strings ST11 to ST1m, ST21 to ST2m may extend along a vertical direction (Z direction). Within the memory block MB, m strings may be arranged in a row direction (X direction). In FIG. 3, two strings are illustrated as being arranged in a column direction (Y direction), but this is for illustrative purposes only, and three or more strings may be arranged in the column direction (Y direction).

The strings ST11 to ST1m, ST21 to ST2m may be configured identically. For example, the string ST11 may include a source selection transistor SST, memory cells MC1 to MCn, and a drain selection transistor DST, coupled in series with each other between the source line SL and the bit line BL1. A source of the source selection transistor SST may be coupled to the source line SL, and a drain of the drain selection transistor DST may be coupled to the bit line BL1. The memory cells MC1 to MCn may be coupled in series with each other between the source selection transistor SST and the drain selection transistor DST. In an embodiment, a plurality of source selection transistors may be coupled in series between the source line SL and the memory cell MC1. In an embodiment, a plurality of drain selection transistors may be coupled in series between the bit line BL1 and the memory cell MCn.

Source selection transistors at the same position in a vertical direction may be configured as shown below. Specifically, the gates of the source selection transistors of strings arranged in the same row may be coupled to the same source selection line. For example, the gates of the source selection transistors of strings ST11 to ST1m in a first row may be coupled to a source selection line SSL1. For example, the gates of the source selection transistors of a second row of strings ST21 to ST2m may be coupled to a source selection line SSL2.

In an embodiment, source selection transistors of two or more rows of strings may be coupled in common to a single source selection line. For example, the source selection transistors of the first and second rows of strings ST11 to ST1m, ST21 to ST2m may be coupled in common to one source selection line, and the source selection transistors of the third and fourth rows of strings may be coupled in common to one source selection line.

Drain selection transistors at the same position in a vertical direction may be configured as shown below. Specifically, the gates of the drain selection transistors of strings arranged in the same row may be coupled to the same drain selection line. For example, the gates of the drain selection transistors of the strings ST11 to ST1m of the first row may be coupled to the drain selection line DSL1. For example, the gates of the drain selection transistors of the second row of the strings ST21 to ST2m may be coupled to the drain selection line DSL2.

Strings arranged in the same column may be coupled to the same bit line. For example, strings ST11, ST21 in a first column may be coupled to the bit line BL1. For example, strings ST1m, ST2m in an mth column may be coupled to the bit line BLm.

Gates of memory cells at the same position in a vertical direction may be coupled to the same word line. For example, in strings ST11 to ST1m and ST21 to ST2m, memory cells that are at the same position in a direction perpendicular to the memory cell MC1 may be coupled to the word line WL1.

Among the memory cells, memory cells coupled to the same word line in the same row may constitute one memory region. For example, memory cells coupled to the word line WL1 in the first row may constitute one memory region MR11. For example, memory cells coupled to the word line WL1 in the second row may constitute one memory region MR12. For example, memory cells coupled to word line WL2 in the first row may constitute one memory region MR21. Depending on the number of rows, each word line may be coupled to multiple memory regions. The memory cells constituting one memory region may be accessed simultaneously. The words “simultaneous” and “simultaneously” as used herein with respect to processes mean that the processes take place on overlapping intervals of time. For example, if a first process takes place over a first interval of time and a second process takes place simultaneously over a second interval of time, then the first and second intervals at least partially overlap each other such that there exists a time at which the first and second processes are both taking place.

In an embodiment, the memory block MB may be further coupled to at least one dummy word line other than the word lines WL1 to WLn. In this case, the memory block MB may further include dummy memory cells coupled to dummy word lines.

A memory cell may be turned on or turned off according to a threshold voltage when a predetermined read voltage is applied to the memory cell through a selected word line among the word lines WL1 to WLn. Specifically, a memory cell having a threshold voltage lower than the read voltage may be turned on in response to the read voltage, and a memory cell having a threshold voltage higher than the read voltage may be turned off. When the memory cell is turned on, the memory cell may change a state of a precharged bit line (i.e., a voltage level of the bit line or a current flowing through the bit line), and a page buffer connected to the corresponding bit line may determine whether the threshold voltage of the memory cell is lower or higher than the read voltage by sensing a state of the bit line. For example, the page buffer may store a sensing result as “1” (or “0”) when the memory cell is determined to have a threshold voltage lower than the read voltage, and may store the sensing result as “0” (or “1”) when the memory cell is determined to have a threshold voltage higher than the read voltage. Accordingly, a read operation on the memory cells connected to the selected word line may be performed by determining threshold voltages of each of the memory cells based on one or more read voltages.

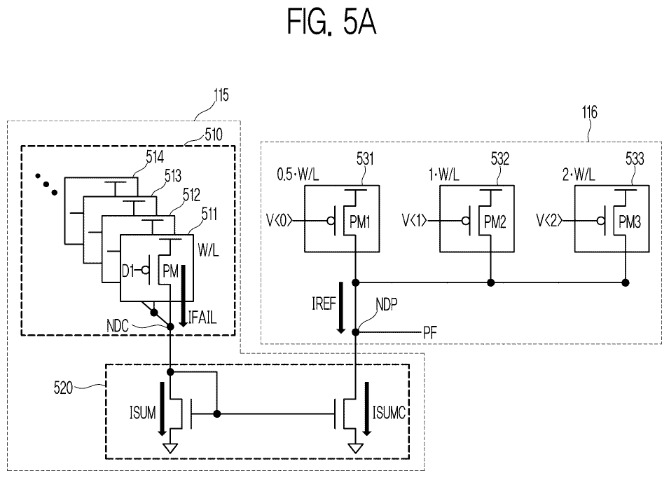

FIG. 4 is a circuit diagram illustrating a page buffer PB according to an embodiment. Each of the page buffers PB1 to PBm of FIG. 2 may be configured similarly to the page buffer PB.

Referring to FIG. 4, the page buffer PB may include a bit line selection circuit 401, a precharge circuit 402, a plurality of latches 403 to 405, and a multiplication circuit 406. The page buffer PB may be connected to a corresponding bit line BL among the bit lines BL1 to BLm.

The bit line selection circuit 401 may be configured to form a data path by connecting the bit line BL and an intermediate node CN according to control of the control circuit 111.

The precharge circuit 402 may be connected to the intermediate node CN and may be configured to precharge the intermediate node CN according to control of the control circuit 111. The precharge circuit 402 may precharge the bit line BL through the intermediate node CN to perform a sensing operation.

The plurality of latches 403 to 405 may be connected to the intermediate node CN and may store data to be stored in a memory cell connected to the bit line BL and data read from the memory cell connected to the bit line BL according to control of the control circuit 111. Also, a pre-designated first latch 403 among the plurality of latches 403 to 405 may store inputs x on which a multiplication operation is performed in a deep neural network computing operation. Also, a pre-designated second latch 404 among the plurality of latches 403 to 405 may store a parameter p on which a multiplication operation with the inputs x is performed in the deep neural network computing operation.

The multiplication circuit 406 may be connected to the intermediate node CN and may perform a multiplication operation in a deep neural network computing operation according to control of the control circuit 111. The multiplication circuit 406 may receive the inputs x stored in the first latch 403 and the parameter p stored in the second latch 404 and may perform the multiplication operation 416.

In an embodiment, the multiplication circuit 406 may be implemented to perform an AND operation or an XNOR operation, but the embodiment of the present disclosure is not limited thereto.

In an embodiment, the multiplication circuit 406 may include arithmetic and/or logic circuitry configured to perform a multiplication operation between input data stored in the first latch 403 and parameter data stored in the second latch 404 during a deep neural network computing operation. The multiplication circuit 406 may be coupled to the intermediate node CN and may operate under control of the control circuit 111. The arithmetic and/or logic circuitry may include combinational logic gates, arithmetic logic units, and bit level processing circuits configured to generate a multiplication result 416 based on the received inputs x and parameters p. In some embodiments, the multiplication circuit 406 may be implemented as a digital multiplier configured to perform binary or multi bit multiplication. In other embodiments, the multiplication circuit 406 may be implemented using logic based multiplication circuitry configured to perform an AND operation, an XNOR operation, or a combination thereof, corresponding to multiplication operations in binary or quantized neural network models. The multiplication circuit 406 may further include output latching or buffering circuitry configured to store or forward the multiplication result to subsequent processing circuitry through the intermediate node CN.

In an embodiment, input of the program data PD to the page buffer PB and output of the read data RD from the page buffer PB may be performed through at least one latch among the plurality of latches 403 to 405, and the latch may be configured in various manners according to an implementation scheme.

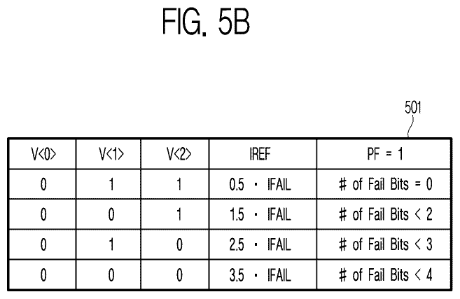

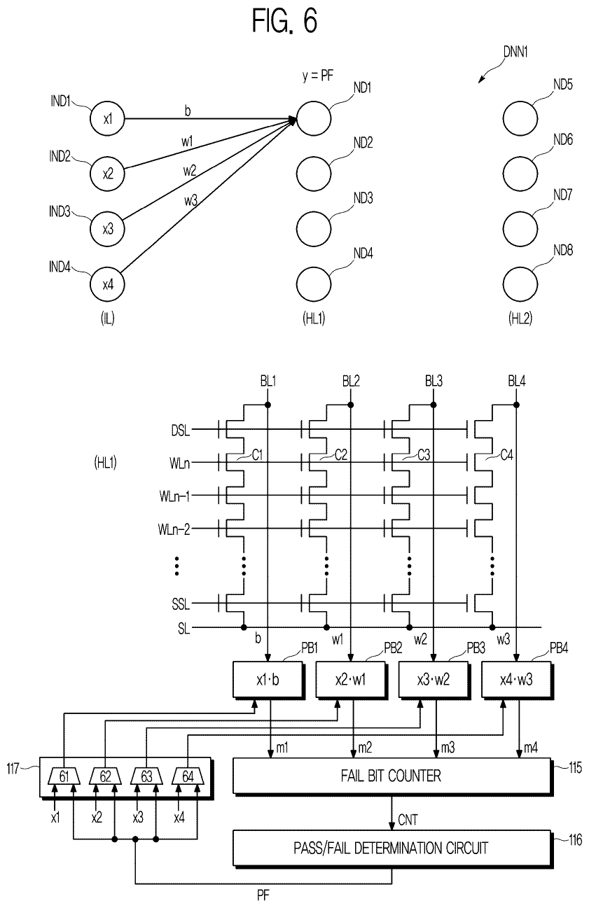

FIG. 5A is a diagram illustrating the fail bit counter 115 and the pass/fail determination circuit 116 according to an embodiment of the present disclosure. The numbers of components in FIG. 5A may be examples. FIG. 5B is a table 501 illustrating a pass/fail result according to a reference signal according to an embodiment of the present disclosure.

Referring to FIG. 5A, the fail bit counter 115 may include a determination circuit 510 and a mirror circuit 520.

The determination circuit 510 may supply, to a common node NDC, a summation current ISUM corresponding to the number of bits having a value of “0” among data (i.e., the verification data VD or the multiplication results m) received from one or more page buffers among the plurality of page buffers 114. According to a structure of the page buffer PB, a fail bit may have a value of “0”.

Specifically, the determination circuit 510 may include fail bit determination circuits 511 to 514. The fail bit determination circuits 511 to 514 may be respectively connected to one or more page buffers among the plurality of page buffers 114. Each of the fail bit determination circuits 511 to 514 may selectively supply a current to the common node NDC according to a value of data received from a corresponding page buffer. Currents flowing from the fail bit determination circuits 511 to 514 may be accumulated in the common node NDC as the summation current ISUM.

For example, the fail bit determination circuit 511 may include a PMOS transistor PM. The PMOS transistor PM may receive data D1 transmitted from a corresponding page buffer as a gate input. The PMOS transistor PM may supply a current IFAIL to the common node NDC in response to the data D1 having a value of “0”. An amount of the current IFAIL may be determined according to a ratio of a channel width to a channel length (W/L) of the PMOS transistor PM. The fail bit determination circuits 512 to 514 may be configured and operate similarly to the fail bit determination circuit 511.

The mirror circuit 520 may be configured to replicate, as a replica current ISUMC flowing from a determination node NDP to a ground node, the summation current ISUM flowing through the common node NDC. The replica current ISUMC may correspond to the count result CNT of FIG. 2.

The pass/fail determination circuit 116 may supply, to the determination node NDP, a reference current IREF corresponding to a predetermined reference value in response to a reference signal V<2:0> corresponding to the reference value. The pass/fail determination circuit 116 may include unit circuits 531 to 533. The unit circuits 531 to 533 may receive respective bits constituting the reference signal V<2:0>. The bit signals V<0>, V<1>, and V<2> respectively correspond to bits constituting the reference signal V<2:0>. Each of the unit circuits 531 to 533 may selectively supply a current to the determination node NDP in response to a corresponding bit signal. The unit circuits 531 to 533 may be configured to respectively supply, to the determination node NDP, currents having different scaling factors of the current IFAIL flowing through an activated fail bit determination circuit.

For example, the unit circuits 531 to 533 may respectively include PMOS transistors PM1 to PM3. The PMOS transistor PM1 may receive a bit signal V<0> as a gate input, the PMOS transistor PM2 may receive a bit signal V<1> as a gate input, and the PMOS transistor PM3 may receive a bit signal V<2> as a gate input. With respect to a ratio of a channel width to a channel length (W/L) of each fail bit determination circuit, the PMOS transistor PM1 may be configured to have a ratio corresponding to 0.5 times, the PMOS transistor PM2 may be configured to have a ratio corresponding to 1 time, and the PMOS transistor PM3 may be configured to have a ratio corresponding to 2 times.

Accordingly, referring to the table 501, for example, when only the unit circuits 531 and 533 are activated in response to the reference signal V<2:0>, a reference current IREF corresponding to 2.5 times the current IFAIL flowing through an activated fail bit determination circuit may be supplied to the determination node NDP.

The determination node NDP may output, as the pass/fail result PF, a result obtained by comparing the reference current IREF with the replica current ISUMC. The determination node NDP may output “1” as the pass/fail result PF when the replica current ISUMC is less than the reference current IREF, and may output “0” as the pass/fail result PF when the replica current ISUMC is greater than the reference current IREF.

The table 501 illustrates numbers of fail bits for which the pass/fail result PF is output as “1” with respect to exemplary values of the reference current IREF. For example, when the reference current IREF corresponding to 2.5 times the current IFAIL flowing through an activated fail bit determination circuit is supplied to the determination node NDP, the pass/fail result PF may be output as “0” when the number of fail bits counted by the fail bit counter 115 is three, and the pass/fail result PF may be output as “1” when the number of fail bits counted by the fail bit counter 115 is two.

Accordingly, in a deep neural network computing operation, the fail bit determination circuits 511 to 514 may respectively receive multiplication results m from corresponding page buffers and may determine whether each of the multiplication results m matches “0”, thereby outputting the replica current ISUMC corresponding to the number of “0”s among the multiplication results m. Because the number of “0”s among the multiplication results m has a complement relationship with respect to the number of “1”s based on the total number of the multiplication results m, an operation of the fail bit counter 115 may, as a result, reflect a summation operation at each node ND in a deep neural network computing operation.

In a deep neural network computing operation, when the replica current ISUMC output from the fail bit counter 115 is less than the reference current IREF (that is, when a summation result is greater than a predetermined reference value), the pass/fail determination circuit 116 may output “1” as the pass/fail result PF, and when the replica current ISUMC is greater than the reference current IREF (that is, when the summation result is less than the reference value), the pass/fail determination circuit 116 may output “0” as the pass/fail result PF. As a result, the pass/fail determination circuit 116 may perform an activation operation on the summation result in the deep neural network computing operation, thereby nonlinearly transforming the summation result and outputting the node computing result y of each node ND.

According to a structure of the page buffer PB, when a fail bit has a value of “0”, the fail bit counter 115 may count the number of “0”s and may output the replica current ISUMC corresponding thereto as the count result CNT. In addition, the pass/fail determination circuit 116 may be configured to compare the replica current ISUMC with the reference current IREF. In this manner, although the embodiment of FIG. 5A is processed based on a complementary method instead of outputting a direct summation result, the pass/fail result PF finally output may accurately reflect an actual summation operation result and an activation operation result.

In an embodiment, when a fail bit has a value of “1”, the fail bit counter 115 may be configured to count the number of “1”s, unlike an embodiment of FIG. 5A, and the count result CNT output from the fail bit counter 115 will reflect a result of performing a summation operation on multiplication results m.

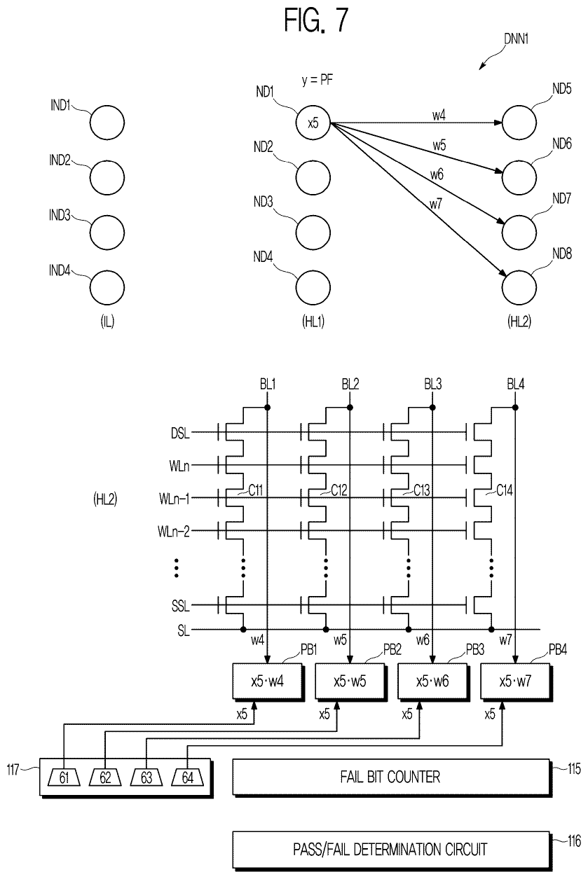

FIGS. 6 and 7 are diagrams illustrating a deep neural network computing operation of the memory device 100 according to an embodiment of the present disclosure. In FIGS. 6 and 7, the memory device 100 may implement a deep neural network DNN1 in which an input layer IL includes four input nodes IND1 to IND4, a first hidden layer HL1 includes first to fourth nodes ND1 to ND4, and a second hidden layer HL2 includes fifth to eighth nodes ND5 to ND8.

Referring to FIG. 6, parameters b, w1, w2, and w3 respectively corresponding to input connections of the first node ND1 may be stored in memory cells C1 to C4 connected to a word line WLn. The memory cells C1 to C4 may have threshold voltages respectively corresponding to the parameters b, w1, w2, and w3 through a program operation. The parameters b, w1, w2, and w3 may include a bias b and weights w1, w2, and w3.

The input circuit 117 may include selection circuits 61 to 64. The selection circuits 61 to 64 may respectively receive external inputs x1 to x4 and may also receive a pass/fail result PF. Each of the selection circuits 61 to 64 may output one of a corresponding external input and the pass/fail result PF under control of the control circuit 111.

Specifically, each of the selection circuits 61 to 64 may output a corresponding external input so that an operation of the first hidden layer HL1 is performed, and may output the pass/fail result PF so that an operation of a subsequent hidden layer after the first hidden layer HL1 is performed.

Page buffers PB1 to PB4 may be respectively connected to the selection circuits 61 to 64. Each of the page buffers PB1 to PB4 may receive and store an output of a corresponding selection circuit among the selection circuits 61 to 64.

In an embodiment, an output path from the selection circuits 61 to 64 to the page buffers PB1 to PB4 may be controlled differently from that illustrated according to an input connection structure between the input layer IL and nodes of a plurality of hidden layers.

In an embodiment, the selection circuits 61 to 64 may receive the program data PD of FIG. 2 as external inputs x1 to x4 and may output the external inputs x1 to x4 to the page buffers PB1 to PB4.

To specifically describe an operation corresponding to the first node ND1 of the first hidden layer HL1, the selection circuits 61 to 64 may respectively transmit the external inputs x1 to x4 to the page buffers PB1 to PB4 under control of the control circuit 111. Each of the external inputs x1 to x4 may be stored in the first latch 403 included in a corresponding page buffer. The external inputs x1 to x4 may be included in the external input data DIN of FIG. 2.

Also, a read operation may be performed on the memory cells C1 to C4. Specifically, by applying a read voltage to the word line WLn, the parameters b, w1, w2, and w3 stored in the memory cells C1 to C4 may be respectively read to the page buffers PB1 to PB4 through bit lines BL1 to BL4. Each of the parameters b, w1, w2, and w3 may be stored in the second latch 404 included in a corresponding page buffer.

The page buffers PB1 to PB4 may respectively perform multiplication operations on the external inputs x1 to x4 and the parameters b, w1, w2, and w3 and may output multiplication results m1 to m4.

The fail bit counter 115 may receive the multiplication results m1 to m4 and may output a count result CNT by performing a counting operation on the multiplication results m1 to m4. The count result CNT may correspond to a result of performing a summation operation on the multiplication results m1 to m4.

The pass/fail determination circuit 116 may, based on the count result CNT output from the fail bit counter 115, output the pass/fail result PF as “1” when the summation result is greater than a predetermined reference value, and output the pass/fail result PF as “0” when the summation result is not greater than the reference value. The pass/fail result PF may be a result obtained by performing an activation operation on the summation result and may be the node computing result y of the first node ND1.

The pass/fail result PF output from the pass/fail determination circuit 116 may be transmitted to the input circuit 117.

Referring to FIG. 7, weights w4 to w7 respectively corresponding to input connections from the first node ND1 to the fifth to eighth nodes ND5 to ND8 may be stored in memory cells C11 to C14 connected to a word line WLn−1.

For an operation of the second hidden layer HL2, the selection circuits 61 to 64 may transmit, under control of the control circuit 111, the node computing result y of the first node ND1, that is, the pass/fail result PF received from the pass/fail determination circuit 116, to the page buffers PB1 to PB4 respectively as an input x5 delivered from the first node ND1 to the fifth to eighth nodes ND5 to ND8.

Also, a read operation may be performed on the memory cells C11 to C14. Specifically, by applying a read voltage to the word line WLn−1, the parameters w4 to w7 stored in the memory cells C11 to C14 may be respectively read to the page buffers PB1 to PB4 through the bit lines BL1 to BL4.

The page buffers PB1 to PB4 may respectively perform multiplication operations on the input x5 and the parameters w4 to w7. Thereafter, an operation of the second hidden layer HL2 may be performed similarly to that described for the first hidden layer HL1.

In an embodiment, in a structure that is not a Fully Connected Deep Neural Network (FC DNN), weights corresponding to paths that are not actually connected may be stored as “0” in memory cells. Accordingly, the memory device 100 may operate such that both a fully connected deep neural network and a deep neural network other than the fully connected deep neural network are implemented.

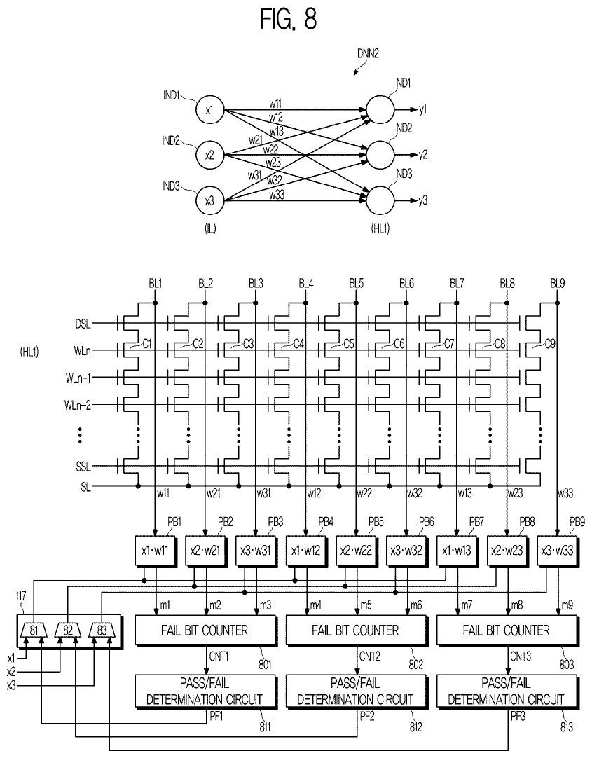

FIG. 8 is a diagram illustrating a deep neural network computing operation of the memory device 100 according to an embodiment of the present disclosure.

Referring to FIG. 8, the memory device 100 may implement a deep neural network DNN2 in which an input layer IL includes three input nodes IND1 to IND3 and a first hidden layer HL1 includes three first to third nodes ND1 to ND3.

The input circuit 117 may include selection circuits 81 to 83. The selection circuits 81 to 83 may respectively receive external inputs x1 to x3 and pass/fail results PF1 to PF3. An output of the selection circuit 81 may be connected to page buffers PB1, PB4, and PB7, an output of the selection circuit 82 may be connected to page buffers PB2, PB5, and PB8, and an output of the selection circuit 83 may be connected to page buffers PB3, PB6, and PB9. Each of the selection circuits 81 to 83 may output one of a corresponding external input and a corresponding pass/fail result to corresponding page buffers under control of the control circuit 111.

Specifically, each of the selection circuits 81 to 83 may output a corresponding external input so that an operation of the first hidden layer HL1 is performed, and may output a corresponding pass/fail result so that an operation of a hidden layer after the first hidden layer HL1 is performed. In an embodiment, an output path from the selection circuits 81 to 83 to the page buffers PB1 to PB9 may be controlled differently from that illustrated according to a connection structure between the input layer IL and nodes of a plurality of hidden layers.

In an embodiment, the selection circuits 81 to 83 may receive the program data PD of FIG. 2 as external inputs x1 to x3 and may output the external inputs x1 to x3 to the page buffers PB1 to PB9.

Also, the memory device 100 may include fail bit counters 801 to 803 and pass/fail determination circuits 811 to 813.

Each of the fail bit counters 801 to 803 may receive multiplication results from a corresponding set of page buffers. For example, the fail bit counter 801 may receive multiplication results m1 to m3 from the page buffers PB1 to PB3, the fail bit counter 802 may receive multiplication results m4 to m6 from the page buffers PB4 to PB6, and the fail bit counter 803 may receive multiplication results m7 to m9 from the page buffers PB7 to PB9. Each of the fail bit counters 801 to 803 may operate similarly to the fail bit counter 115 with respect to the received multiplication results, and the fail bit counters 801 to 803 may respectively output count results CNT1 to CNT3.

The pass/fail determination circuits 811 to 813 may be respectively connected to the fail bit counters 801 to 803 and may respectively receive the count results CNT1 to CNT3 from the fail bit counters 801 to 803. Each of the pass/fail determination circuits 811 to 813 may operate similarly to the pass/fail determination circuit 116 with respect to a corresponding count result, and the pass/fail determination circuits 811 to 813 may respectively output pass/fail results PF1 to PF3.

Memory cells C1 to C9 connected to a word line WLn may store weights w11, w21, w31, w12, w22, w32, w13, w23, and w33 respectively corresponding to input connections of the first to third nodes ND1 to ND3. Specifically, the memory cells C1 to C3 may store the weights w11, w21, and w31 respectively corresponding to input connections of the first node ND1, the memory cells C4 to C6 may store the weights w12, w22, and w32 respectively corresponding to input connections of the second node ND2, and the memory cells C7 to C9 may store the weights w13, w23, and w33 respectively corresponding to input connections of the third node ND3.

To specifically describe an operation performed in the first hidden layer HL1, the selection circuits 81 to 83 may transmit the external inputs x1 to x3 to the page buffers PB1 to PB9 under control of the control circuit 111. Specifically, the selection circuit 81 may transmit the external input x1 to the page buffers PB1, PB4, and PB7, the selection circuit 82 may transmit the external input x2 to the page buffers PB2, PB5, and PB8, and the selection circuit 83 may transmit the external input x3 to the page buffers PB3, PB6, and PB9.

Also, a read operation may be performed on the memory cells C1 to C9. Specifically, by applying a read voltage to the word line WLn, weights w11, w21, w31, w12, w22, w32, w13, w23, and w33 stored in the memory cells C1 to C9 may be respectively read to the page buffers PB1 to PB9 through bit lines BL1 to BL9.

Each of the page buffers PB1 to PB9 may perform a multiplication operation on the received external input and the weight, and the page buffers PB1 to PB9 may output multiplication results m1 to m9.

An operation corresponding to the first node ND1 may be implemented through the page buffers PB1 to PB3 that perform multiplication operations and output multiplication results m1 to m3, the fail bit counter 801 that performs a summation operation on the multiplication results m1 to m3 and outputs the count result CNT1, and the pass/fail determination circuit 811 that performs an activation operation on the count result CNT1. The pass/fail result PF1 may correspond to a node computing result y1 of the first node ND1.

Also, an operation corresponding to the second node ND2 may be implemented through the page buffers PB4 to PB6 that perform multiplication operations and output multiplication results m4 to m6, the fail bit counter 802 that performs a summation operation on the multiplication results m4 to m6 and outputs the count result CNT2, and the pass/fail determination circuit 812 that performs an activation operation on the count result CNT2. The pass/fail result PF2 may correspond to a node computing result y2 of the second node ND2.

Also, an operation corresponding to the third node ND3 may be implemented through the page buffers PB7 to PB9 that perform multiplication operations and output multiplication results m7 to m9, the fail bit counter 803 that performs a summation operation on the multiplication results m7 to m9 and outputs the count result CNT3, and the pass/fail determination circuit 813 that performs an activation operation on the count result CNT3. The pass/fail result PF3 may correspond to a node computing result y3 of the third node ND3.

The pass/fail results PF1 to PF3 may be transmitted to the input circuit 117 for an operation to be performed in a hidden layer subsequent to the first hidden layer HL1.

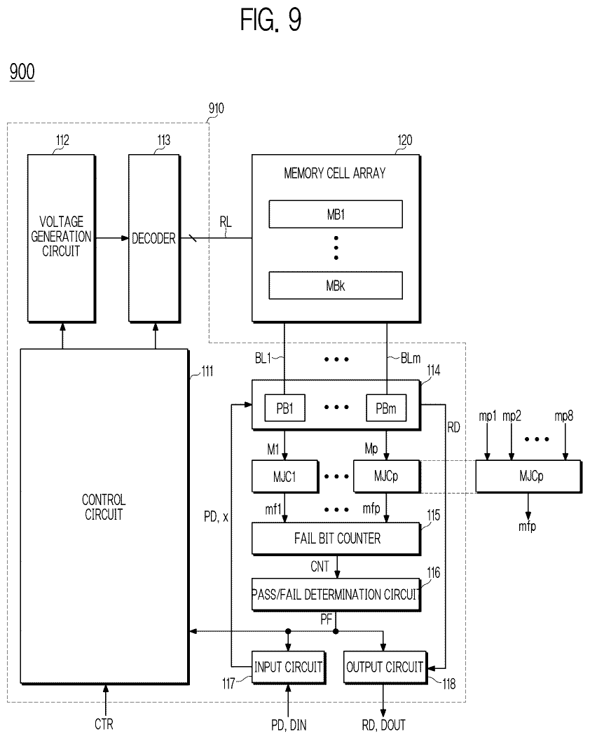

FIG. 9 is a block diagram illustrating a memory device 900 capable of performing a deep neural network computing operation according to an embodiment of the present disclosure.

Referring to FIG. 9, compared with the memory device 100, the memory device 900 may further include majority check circuits MJC1 to MJCp. The remaining circuit configurations of the memory device 900 may be configured similarly to those described with reference to FIG. 2.

Each of the majority check circuits MJC1 to MJCp may be coupled to corresponding page buffers (or a corresponding page buffer group) among the page buffers PB1 to PBm. Each of the majority check circuits MJC1 to MJCp may perform a majority check operation on multiplication results received from the corresponding page buffers and may output a final multiplication result.

Specifically, the majority check circuit MJC1 may compare values of multiplication results M1 received from corresponding page buffers and may determine a final multiplication result mf1 based on the number of multiplication results having an identical value. Similarly, the majority check circuit MJCp may compare values of multiplication results Mp received from corresponding page buffers and may determine a final multiplication result mfp based on the number of multiplication results having an identical value. For example, the multiplication results Mp may include eight multiplication results mp1 to mp8. When five or more of the multiplication results mp1 to mp8 have an identical value, the majority check circuit MJCp may output the corresponding value as the final multiplication result mfp.

The fail bit counter 115 may receive final multiplication results mf1 to mfp from the majority check circuits MJC1 to MJCp and, similarly to that described with reference to FIG. 2, may perform a summation operation on the final multiplication results mf1 to mfp and may output a count result CNT as a result of performing a summation operation.

Although not shown, the fail bit counter 115 may receive the verification data VD from a plurality of page buffers 114 and may perform a counting operation on the verification data VD, as described with reference to FIG. 2.

Accordingly, in an embodiment, even when errors occur in some of the multiplication results, the majority check circuits MJC1 to MJCp may provide a stable result by referring to a majority of the multiplication results, and therefore, reliability of a deep neural network computing operation may be improved.

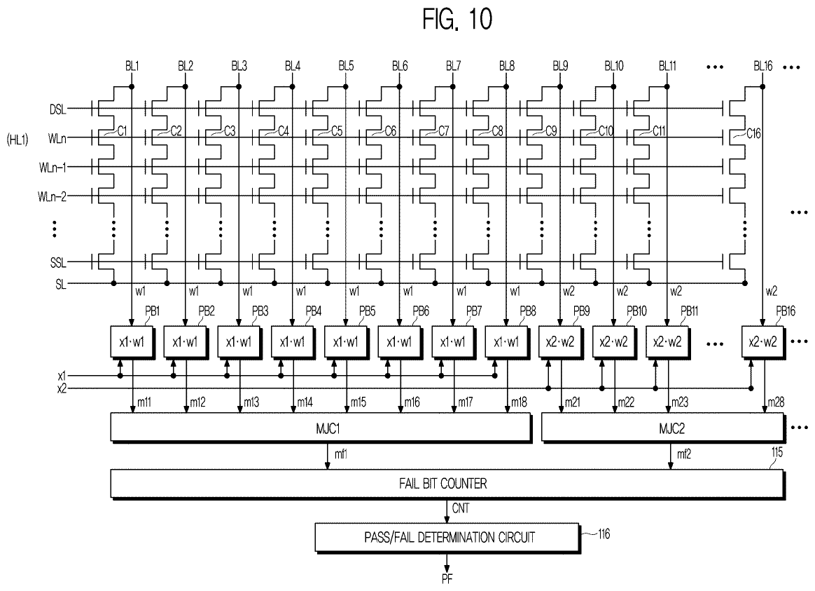

FIG. 10 is a diagram illustrating a deep neural network computing operation of the memory device 900 in an embodiment of the present disclosure.

Referring to FIG. 10, the same weight w1 may be stored in memory cells C1 to C8 connected to a word line WLn and bit lines BL1 to BL8. Also, the same weight w2 may be stored in memory cells C9 to C16 connected to the word line WLn and bit lines BL9 to BL16.

Also, external input x1 may be respectively input to page buffers PB1 to PB8 connected to the bit lines BL1 to BL8 through an input circuit 117 that is not shown. The page buffers PB1 to PB8 may constitute one page buffer group. Also, external input x2 may be respectively input to page buffers PB9 to PB16 connected to the bit lines BL9 to BL16 through the input circuit 117. The page buffers PB9 to PB16 may constitute one page buffer group.

By applying a read voltage to the word line WLn, the same weight w1 stored in the memory cells C1 to C8 may be respectively read to the page buffers PB1 to PB8 through the bit lines BL1 to BL8, and at the same time, the same weight w2 stored in the memory cells C9 to C16 may be respectively read to the page buffers PB9 to PB16 through the bit lines BL9 to BL16.

The page buffers PB1 to PB8 may respectively perform multiplication operations on the external input x1 and the weight w1. Also, the page buffers PB9 to PB16 may respectively perform multiplication operations on the external input x2 and the weight w2.

The majority check circuit MJC1 may receive multiplication results m11 to m18 included in the multiplication results M1 of FIG. 9 from the page buffers PB1 to PB8 and may output a final multiplication result mf1 by performing a majority check operation on the multiplication results m11 to m18. Also, the majority check circuit MJC2 may receive multiplication results m21 to m28 and may output a final multiplication result mf2 by performing a majority check operation on the multiplication results m21 to m28.

In an embodiment, each majority check circuit MJC1 and MJC2 may include majority determination logic implemented using combinational logic circuitry configured to determine a majority value among a plurality of input data values. The majority check circuits may receive multiplication results from corresponding page buffers and may generate a final multiplication result based on a comparison of the received values. For example, the majority check circuit MJC1 may receive multiplication results m11 to m18 from page buffers PB1 to PB8, and the majority check circuit MJC2 may receive multiplication results m21 to m28 from corresponding page buffers. In an embodiment, the majority determination logic may include logic gates, adders, comparators, and threshold detection circuitry configured to count or evaluate the number of multiplication results having a first logic value relative to a second logic value and to output a final multiplication result mf1 or mf2 corresponding to the majority value. In some embodiments, the majority check circuits may be implemented using summation logic followed by comparison logic that determines whether a count of asserted values exceeds a predetermined threshold. The majority check circuits may further include output registers or latches configured to store or forward the final multiplication results to subsequent processing circuitry.

The fail bit counter 115 and the pass/fail determination circuit 116 may operate similarly to that described above.

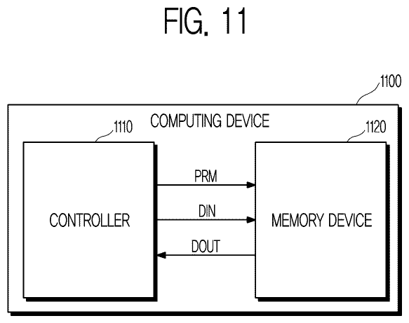

FIG. 11 is a block diagram illustrating a computing device 1100 performing a deep neural network computing operation according to an embodiment of the present disclosure.

The computing device 1100 may include a controller 1110 and a memory device 1120.

The controller 1110 may store parameters PRM such as weights and biases required for a deep neural network computing operation in the memory device 1120 before performing the deep neural network computing operation.

In an embodiment, the parameters PRM may be pre-stored in the memory device 1120 by an external device during a manufacturing process or an initial setting stage.

In an embodiment, the controller 1110 may control some bit lines among bit lines BL1 to BLm such that the bit lines are not used in the deep neural network computing operation. For example, the controller 1110 may store dummy values in memory cells connected to some bit lines. For example, the controller 1110 may store weights respectively corresponding to input connections of a first node of a first hidden layer HL1 in memory cells connected to first bit lines, may store weights respectively corresponding to input connections of a second node of the first hidden layer HL1 in memory cells connected to second bit lines spaced apart from the first bit lines by a predetermined distance, and may store weights respectively corresponding to input connections of a third node of the first hidden layer HL1 in memory cells connected to third bit lines spaced apart from the second bit lines by a predetermined distance. In this case, the controller 1110 may store dummy values in memory cells connected to bit lines between the first bit lines and the second bit lines and between the second bit lines and the third bit lines.

The controller 1110 may control the memory device 1120 to perform a deep neural network computing operation by transmitting external input data DIN to the memory device 1120. The external input data DIN may be provided from an external host device or an application processor.

In an embodiment, the controller 1110 may include one or more processors or processing cores, control logic circuitry, interface circuitry, and control registers configured to manage communication with the memory device 1120. The controller 1110 may further include command generation and sequencing logic configured to generate control commands and timing signals for initiating the deep neural network computing operation, and interface logic configured to transmit the external input data DIN to the memory device 1120 in accordance with predetermined communication protocols.

The memory device 1120 may perform a deep neural network computing operation based on the stored parameters PRM and the external input data DIN under control of the controller 1110 and may output output data DOUT to the controller 1110 as a result of performing the deep neural network computing operation.

The memory device 1120 may include, for example, a structure similar to the memory device 100 illustrated in FIG. 2 or the memory device 900 illustrated in FIG. 9.

Concepts are disclosed in conjunction with examples and embodiments. Those skilled in the art will understand that various modifications, additions, combinations, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to the provided descriptions. All changes within the meaning and range of equivalency of the claims are included within their scope.

What is claimed is:

1. A memory device comprising:
a memory cell array including memory cells connected to word lines and bit lines, the memory cells being NAND flash memory cells; and
a plurality of page buffers configured to, in a deep neural network computing operation, store first values read from first memory cells connected to a first word line among the word lines through the bit lines and configured to respectively perform multiplication operations on inputs and the first values.

2. The memory device of claim 1, wherein each of the plurality of page buffers comprises:
a first latch configured to store a corresponding input data value among the inputs;
a second latch configured to store a corresponding first value among the first values; and
a multiplication circuit configured to perform a multiplication operation on the corresponding input data value stored in the first latch and the corresponding first value stored in the second latch.

3. The memory device of claim 1, further comprising a fail bit counter configured to receive, from the plurality of page buffers, verification data which is a result of a verification operation performed to determine whether an internal operation performed on target memory cells of the memory cell array has been completed, and configured to output a count result by performing a counting operation of counting the number of fail bits in the verification data,
wherein the fail bit counter is configured to output the count result by performing the counting operation on multiplication results output from one or more first page buffers among the plurality of page buffers in the deep neural network computing operation, and the count result corresponds to a result of performing a summation operation on the multiplication results.

4. The memory device of claim 3, further comprising a pass/fail determination circuit configured to output a pass/fail result of the internal operation based on the count result received from the fail bit counter,
wherein the pass/fail determination circuit is configured to output the pass/fail result based on the count result in the deep neural network computing operation, and the pass/fail result corresponds to a result of performing an activation operation on the result of performing the summation operation.

5. The memory device of claim 4, further comprising a control circuit configured to, in the deep neural network computing operation, control a read operation on the first memory cells to perform an operation of a first hidden layer of a deep neural network, and configured to control a read operation on second memory cells connected to a second word line among the word lines to perform an operation of a second hidden layer of the deep neural network,
wherein the first memory cells store parameters corresponding to input connections of nodes of the first hidden layer, and the second memory cells store parameters corresponding to input connections of nodes of the second hidden layer.

6. The memory device of claim 5, further comprising an input circuit configured to, in the deep neural network computing operation, transmit external inputs received from outside to the plurality of page buffers as inputs transferred from an input layer of the deep neural network to the first hidden layer, and configured to transmit the pass/fail result received from the pass/fail determination circuit to at least one selected page buffer among the plurality of page buffers as an input transferred from the first hidden layer to the second hidden layer,
wherein the at least one selected page buffer is selected based on at least one input connection defined between nodes of the first hidden layer and nodes of the second hidden layer.

7. The memory device of claim 6, further comprising:
a second fail bit counter configured to output a second count result by performing a counting operation on second multiplication results output from one or more second page buffers among the plurality of page buffers in the deep neural network computing operation; and
a second pass/fail determination circuit configured to output a second pass/fail result as a result of performing the activation operation on the second count result in the deep neural network computing operation,
wherein the input circuit is configured to transmit the second pass/fail result received from the second pass/fail determination circuit to at least one selected second page buffer among the plurality of page buffers as a second input transferred from the first hidden layer to the second hidden layer.

8. A memory device comprising:
a memory cell array including memory cells connected to word lines and bit lines, the memory cells being NAND flash memory cells;
a plurality of page buffers configured to, in a deep neural network computing operation, store first values read from first memory cells connected to a first word line among the word lines through the bit lines and further configured to respectively perform multiplication operations on inputs and the first values; and
a plurality of majority check circuits respectively connected to a plurality of page buffer groups into which the plurality of page buffers are divided,
wherein each of the plurality of majority check circuits is configured to, in the deep neural network computing operation, perform a majority check operation on multiplication results received from one or more corresponding page buffers included in a corresponding page buffer group and output a final multiplication result.

9. The memory device of claim 8, wherein one or more page buffers included in the same page buffer group among the plurality of page buffer groups respectively perform multiplication operations on the same input and the same first value.

10. The memory device of claim 8, wherein each of the plurality of page buffers comprises:
a first latch configured to store a corresponding input data value among the inputs;
a second latch configured to store a corresponding first value among the first values; and
a multiplication circuit configured to perform a multiplication operation on the corresponding input data value stored in the first latch and the corresponding first value stored in the second latch.

11. The memory device of claim 8, further comprising a fail bit counter configured to receive, from the plurality of page buffers, verification data which is a result of a verification operation performed to determine whether an internal operation performed on target memory cells of the memory cell array has been completed, and configured to output a count result by performing a counting operation of counting the number of fail bits in the verification data,
wherein the fail bit counter is configured to output the count result by performing the counting operation on final multiplication results output from the plurality of majority check circuits in the deep neural network computing operation, and the count result corresponds to a result of performing a summation operation on the final multiplication results.

12. The memory device of claim 11, further comprising a pass/fail determination circuit configured to output a pass/fail result of the internal operation based on the count result received from the fail bit counter,
wherein the pass/fail determination circuit is configured to output the pass/fail result for the count result in the deep neural network computing operation, and the pass/fail result corresponds to a result of performing an activation operation on the result of performing the summation operation.

13. The memory device of claim 12, further comprising a control circuit configured to, in the deep neural network computing operation, control a read operation on the first memory cells to perform an operation of a first hidden layer of a deep neural network, and configured to control a read operation on second memory cells connected to a second word line among the word lines to perform an operation of a second hidden layer of the deep neural network,
wherein the first memory cells store parameters corresponding to input connections of nodes of the first hidden layer, and the second memory cells store parameters corresponding to input connections of nodes of the second hidden layer.

14. The memory device of claim 13, further comprising an input circuit configured to, in the deep neural network computing operation, transmit external inputs received from outside to the plurality of page buffers as inputs transferred from an input layer of the deep neural network to the first hidden layer,
wherein the input circuit is configured to transmit the same external input to one or more page buffers included in the same page buffer group among the plurality of page buffer groups.

15. The memory device of claim 14, wherein the input circuit is configured to transmit the pass/fail result received from the pass/fail determination circuit to at least one selected page buffer among the plurality of page buffers as an input corresponding to an output of the first hidden layer and transferred to the second hidden layer.

16. A computing device comprising:
a memory device including memory cells connected to word lines and bit lines, the memory cells being NAND flash memory cells and including first memory cells connected to a first word line among the word lines, the first memory cells storing first parameters corresponding to input connections of nodes of a first hidden layer of a deep neural network; and
a controller configured to control the memory device to perform a deep neural network computing operation by transmitting external inputs to the memory device,
wherein the memory device further comprises a plurality of page buffers configured to, in the deep neural network computing operation, respectively store the first parameters read from the first memory cells through the bit lines, respectively store the external inputs, and respectively perform multiplication operations on the external inputs and the first parameters.

17. The computing device of claim 16, wherein the memory device further comprises a fail bit counter configured to receive, from the plurality of page buffers, verification data which is a result of a verification operation performed to determine whether an internal operation performed on target memory cells of the memory device has been completed, and configured to output a count result by performing a counting operation of counting the number of fail bits in the verification data,
wherein the fail bit counter is configured to output the count result by performing the counting operation on multiplication results output from one or more first page buffers among the plurality of page buffers in the deep neural network computing operation, and the count result corresponds to a result of performing a summation operation on the multiplication results.

18. The computing device of claim 17, wherein the memory device further comprises a pass/fail determination circuit configured to output a pass/fail result of the internal operation based on the count result received from the fail bit counter,
wherein the pass/fail determination circuit is configured to output the pass/fail result based on the count result in the deep neural network computing operation, and the pass/fail result corresponds to a result of performing an activation operation on the result of performing the summation operation.

19. The computing device of claim 18, wherein the memory cells further include second memory cells connected to a second word line among the word lines and the second memory cells store second parameters corresponding to input connections of nodes of a second hidden layer of the deep neural network.

20. The computing device of claim 19, further comprising a control circuit configured to, in the deep neural network computing operation, control a read operation on the first memory cells to perform an operation of the first hidden layer and configured to control a read operation on the second memory cells to perform an operation of the second hidden layer of the deep neural network.

21. The computing device of claim 19, further comprising an input circuit configured to, in the deep neural network computing operation, transmit the pass/fail result received from the pass/fail determination circuit to at least one selected page buffer among the plurality of page buffers as an input transferred from the first hidden layer to the second hidden layer,
wherein the at least one selected page buffer is selected based on at least one input connection from the first hidden layer to the second hidden layer.
